(19) United States
(12) Patent Application Publication
(10) Pub. No.: US 2011/0231738 A1
(43) Pub. Date: Sep. 22, 2011

(54) ERROR CORRECTION DECODING APPARATUS AND ERROR CORRECTION DECODING METHOD

(76) Inventor: Koji HORISAKI, Yokohama-shi (JP)

(21) Appl. No.: 12/883,623

(22) Filed: Sep. 16, 2010

(30) Foreign Application Priority Data
Mar. 18, 2010 (JP) 2010-063320

(51) Int. Cl. H03M 13/45; G06F 11/10

(52) U.S. Cl. 714/773; 714/780; 714/E11.034

(57) ABSTRACT

According to one embodiment, an error correction decoding apparatus including a hard-decision decoding module which performs hard-decision decoding using a signal with 2 levels per bit as input data and runs a parity check on the input data, a soft-decision decoding module which performs soft-decision decoding using a signal with the number of multiple levels per bit larger than 2 as input data, a start-up control module which controls the start-up of each of the decoding modules, and an output selection module which selects one of the output signals of the decoding modules. The start-up control module causes the output selection module to select the decoding result of the hard-decision decoding module when the parity errors is a permitted value and causes the output selection module to select the decoding result of the soft-decision decoding module when the parity errors has exceeded the permitted value.

### CROSS-REFERENCE TO RELATED APPLICATIONS

This application is based upon and claims the benefit of priority from Japanese Patent Application No. 2010-063320, filed Mar. 18, 2010; the entire contents of which are incorporated herein by reference.

### FIELD

Embodiments described herein relate generally to an error correction decoding apparatus and an error correction decoding method which subject data read from a NAND flash memory or the like to error correction decoding.

### BACKGROUND

In reading data from a NAND flash memory, the reliability of read data can be increased by performing error correction decoding. Generally, hard-decision decoding whose processing speed is high is performed. With this decoding, however, errors might not be corrected sufficiently. In contrast, soft-decision decoding enables more accurate decoding, but the processing time becomes longer.

To overcome the drawbacks, the technique for performing soft-decision decoding on data whose errors could not be corrected in hard-decision decoding in reading data from a NAND flash memory has recently been proposed (refer to Jpn. Pat. Appln. KOKAI Publication No. 2008-16092).

In this method, hard-decision decoding is first performed and, on the basis of the result, soft-decision decoding is performed. Therefore, the following problem arises: even when there is a high probability that hard-decision decoding will lack sufficient error correction capability, hard-decision decoding is always performed. Accordingly, it cannot be said that the overall processing time is shortened sufficiently.

### BRIEF DESCRIPTION OF THE DRAWINGS

FIG. 1 is a block diagram schematically showing the configuration of an error correction decoding apparatus according to a first embodiment;

FIG. 2 is a block diagram showing a NAND flash memory used in the first embodiment;

FIG. 3 is a flowchart to explain the operation of the error correction decoding apparatus according to the first embodiment;

FIG. 4 shows 2-bit 4-level data stored in a memory cell of a 4-level NAND flash memory according to the first embodiment;

FIG. 5 shows the relationship between lower page data and upper page data in the first embodiment;

FIG. 6 is a diagram to explain the procedure for creating soft-value data in the first embodiment;

FIG. 7 is a block diagram schematically showing an error correction decoding apparatus according to a second embodiment;

FIG. 8 is a flowchart to explain the operation of the error correction decoding apparatus according to the second embodiment;

FIG. 9 is a block diagram schematically showing an error correction decoding apparatus according to a third embodiment; and

FIG. 10 is a block diagram schematically showing an error correction decoding apparatus according to a fourth embodiment.

### DETAILED DESCRIPTION

In general, according to one embodiment, there is provided an error correction decoding apparatus which corrects an error in input data and which comprises: a hard-decision decoding module which performs hard-decision decoding using a signal with 2 levels per bit as input data and runs a parity check on the input data; a soft-decision decoding module which performs soft-decision decoding using a signal with the number of multiple levels per bit larger than 2 as input data; a start-up control module which controls the start-up of each of the decoding modules; and an output selection module which selects one of the output signals of the decoding modules and outputs the selected one. The start-up control module causes the output selection module to select the decoding result of the hard-decision decoding module when the number of parity errors is within a permitted value and causes the soft-decision decoding module to start and the output selection module to select the decoding result of the soft-decision decoding module when the number of parity errors has exceeded the permitted value.

Hereinafter, referring to the accompanying drawings, embodiments will be explained.

### First Embodiment

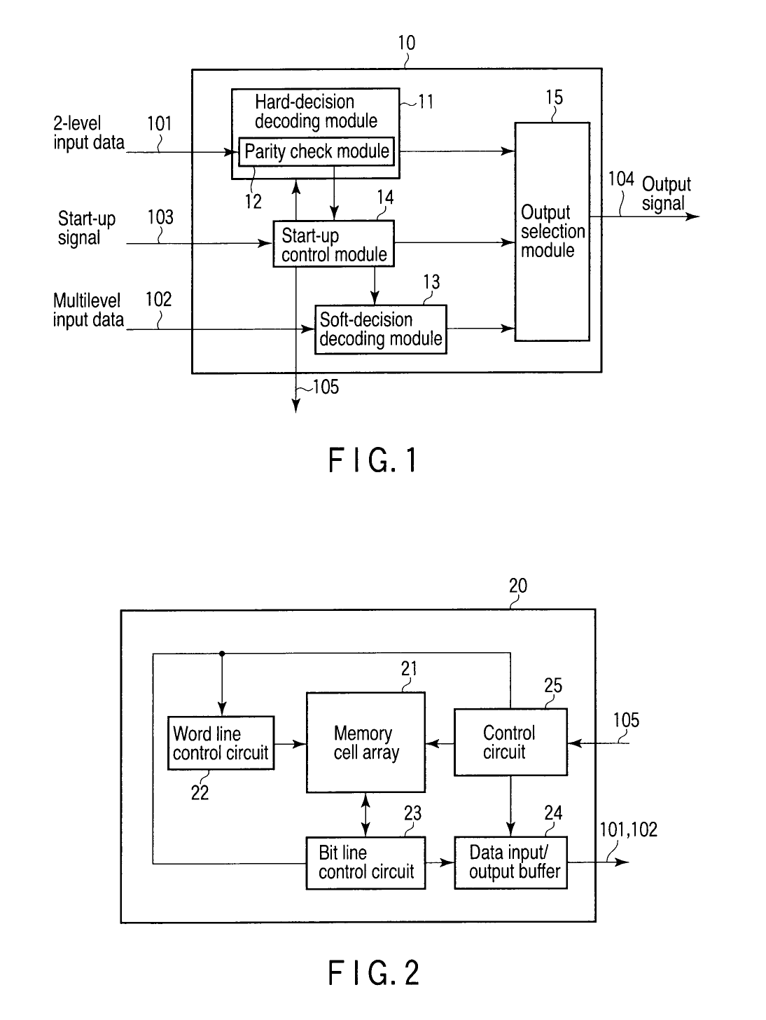

FIG. 1 is a block diagram schematically showing an error correction decoding apparatus according to a first embodiment.

The error correction decoding apparatus of the first embodiment comprises a hard-decision decoding module 11 which performs hard-decision decoding on input data with 2 levels per bit, a soft-decision decoding module 13 which performs soft-decision decoding on input data with multiple levels per bit, a startup control module 14 which controls the start of each of hard-decision decoding and soft-decision decoding, and an output selection module 15 which selects the result of either hard-decision decoding of soft-decision decoding and outputs the selected one.

A signal with 2 levels per bit is input as input data 101 from a NAND flash memory to the hard-decision decoding module 11. The hard-decision decoding module 11 performs decision decoding by using one threshold value for one bit. The hard-decision decoding module 11 includes a parity check module 12 which detects a data error in the input data 101 by using redundant data. A NAND flash memory inputs a signal with the number of multiple levels per bit larger than 2 as input data 102 to the soft-decision decoding module 13. The soft-decision decoding module 13 performs decision decoding by using a plurality of threshold values for one bit. The start-up control module 108 starts the hard-decision decoding module 11 and soft-decision decoding module 13 on the basis of a start-up signal 103 input from a NAND flash memory and selects an output signal 104 from the output selection module 15 according to the number of parity errors detected by the parity check module 12. The start-up control module 14, when stating the soft-decision decoding module 13, sends a control signal 105 to a NAND flash memory described later.

FIG. 2 is a block diagram of a NAND flash memory 20 used in the first embodiment.

A memory cell array 21 is configured to have memory cells arranged in a matrix. The memory cells store data. Although not shown, the memory cell array 21 includes a plurality of bit lines, a plurality of word lines, and a common source line, with electrically rewritable memory cells being arranged in a matrix at the intersections of the bit lines and word lines. Not only multilevel data as information bits but also redundant data added to information bits for error correction are stored in the memory cells.

Connected to the memory cell array 21 are a word line control circuit 22 for controlling a word line voltage and a bit line control circuit 23 for controlling the bit lines voltage. The bit line control circuit 23 is a sense amplifier/data latch circuit which has not only the function of reading data from a memory cell in the memory cell array 21 via a bit line but also a data latch function of holding read data or write data. In addition, the bit line control circuit 23 applies a write control voltage to a memory cell in the memory cell array 21 via a bit line, thereby writing data into the memory cell.

The data read from a memory cell in the memory cell array 21 is output to the outside via a bit line control circuit 23 and a data input/output buffer 24. Write data input to a data input/output terminal from the outside is input to the bit line control circuit 23, thereby writing data into a specified memory cell.

To write and read 2-level data in a read operation, the word line control circuit 22 applies to a word line a read voltage, a verify voltage, and a write voltage as word line voltages. In addition to this, to create soft-value data, the word line control circuit 22 applies a plurality of voltages (soft-value read voltages) whose magnitudes are between the upper and lower limits of a threshold value distribution of the stored data in a memory cell as word line voltages to a word line.

The memory cell array 21, word line control circuit 22, bit line control circuit 23, and data input/output buffer 24 are connected to the control circuit 25 and are operated under the control of the control circuit 25.

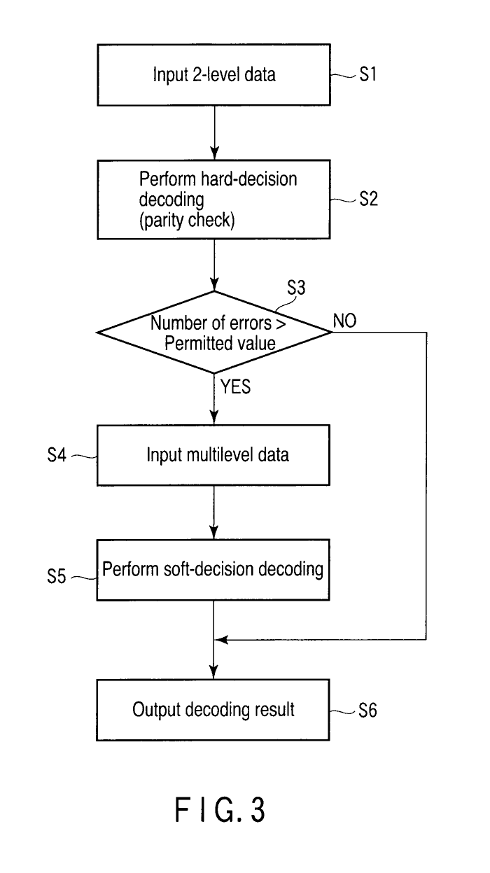

Next, the operation of the first embodiment will be explained with reference to a flowchart shown in FIG. 3.

First, ordinary 2-level data is read from the NAND flash memory 20 and input to the hard-decision decoding module 11 (step S1). The memory cells of the NAND flash memory 20 are not limited to those which store 2-level data and may be those which store multilevel data. In the case of a multilevel memory, multilevel data is converted into 2-level data per bit and the resulting 2-level data is input.

Then, the hard-decision decoding module 11 subjects the input 2-level data to hard-decision decoding (step S2). Specifically, a parity check is performed using redundant data included in the input data. The number of parity errors in a plurality of data items is accumulated and the resulting number is compared with a permitted value (step S3). In an error detecting method, for example, the fact that the process of decoding low-density parity-check (LDPC) code involves a parity check of a plurality of rows is used effectively.

If it has been determined in step S3 that the number of parity errors is not less than the permitted value, that is, if many errors have been detected in the input data or the intermediate result of hard-decision decoding, the start-up control module 14 sends a control instruction to the NAND flash memory 20. Then, multilevel data is read from the NAND flash memory 20 in soft-value reading and the read data is input to the soft-decision decoding module 13 (step S4). That is, originally, 2-level data is read as multilevel data by using a plurality of threshold values. Then, the soft-decision decoding module 13 subjects the multilevel data to soft-decision decoding (step S5).

Then, the output selection module 15 outputs the decoding result of the hard-decision decoding module 11 or soft-decision decoding module 13 (step S6). That is, if many errors have not been detected in the input data or the intermediate result of hard-decision decoding (or if the number of parity errors is not more than the permitted value in step S3), the output selection module 15 selects the decoding result of the hard-decision decoding module 11 and outputs the selected result as the output of the error correction decoding apparatus 10. On the other hand, if many errors have been detected in the input data or the intermediate result of hard-decision decoding (or if the number of parity errors exceeds the permitted value in step S3), the output selection module 15 selects the decoding result of the soft-decision decoding module 13 and outputs the selected result as the output signal 104 of the error correction decoding apparatus 10.

As described above, with the first embodiment, the error correction decoding apparatus 10 is provided with the hard-decision decoding module 11 and soft-decision decoding module 13 and performs soft-decision decoding to complement the preceding decoding if many errors have been detected in hard-decision decoding, thereby enabling accurate decoding. Moreover, soft-decision decoding is started before the completion of hard-decision decoding, which produces the effect of shortening the overall processing time even if soft-decision decoding is performed.

More specifically, the operation when a NAND flash memory uses 4-level memory cells will be explained.

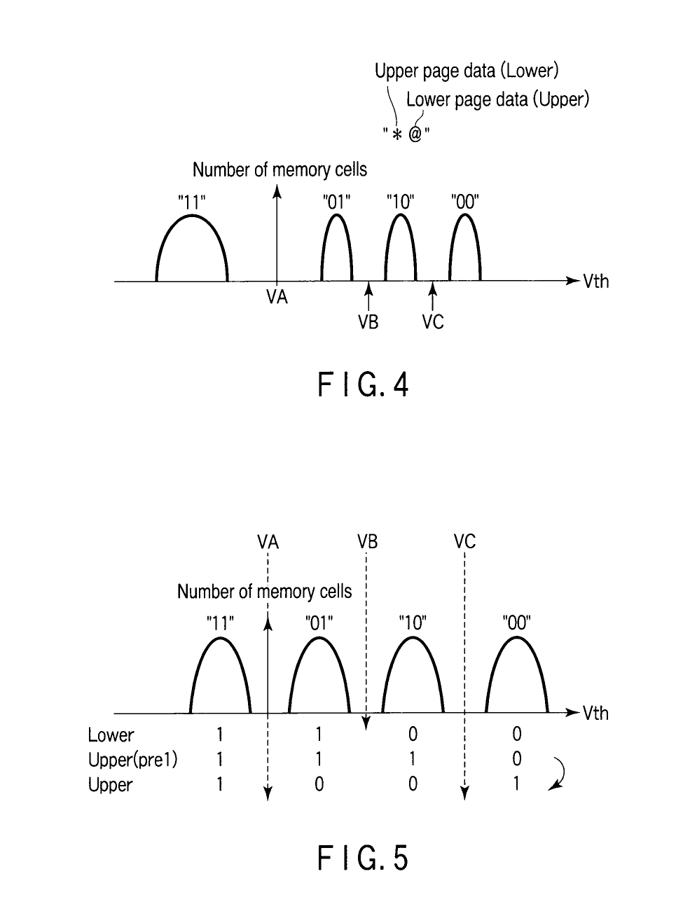

A 4-level NAND flash memory is so configured that the threshold voltage of one memory cell can have four distributions. FIG. 4 shows 2-bit 4-level data (data “11,” “10,” “01,” “00”) stored in a memory cell of the 4-level NAND flash memory and the distributions of threshold voltages (Vth) of the memory cell. In FIG. 4, VA, VB, and VC indicate voltages (multibit-data read voltages) applied to the selected word line when four items of data are read.

After block erasure, the memory cell holds data “11,” having a negative threshold voltage Vth. The memory cell holding written data “01,” “10,” or “00” has a positive threshold voltage Vth. In the written state, data “01” has the lowest threshold voltage, data “00” has the highest threshold voltage, and data “10” has a threshold voltage intermediate between data “01” and data “00.”

Here, 2-bit data in one memory cell is composed of lower-page data and upper-page data. Lower-page data and upper-page data are written into a memory cell by separate write operations, that is, two write operations. When data “*@” is given, * represents upper-page data and @ represents lower-page data.

The hard-decision decoding module 11 corrects an error in multibit data (upper-page data, lower-page data) read by applying multibit data read voltages VA, VB, VC to word line WL on the basis of redundant data for error correction added to the multibit data. Although the redundant data can be stored in a memory cell in the same sector as that in which read multibit data is stored and they can be read at the same time, it is not particularly limited to this method.

The soft-decision decoding module 13 calculates the certainty (likelihood) of read multibit data on the basis of soft-value data created by the bit line control circuit 23. The bit line control circuit 23 creates soft-value data on the basis of data read when the soft-value read voltage is applied to word line WL. A concrete example of the soft data will be described later. The soft-decision decoding module 13 includes, for example, a likelihood table (not shown) which stores soft-value data and likelihood in such a manner that they are related to each other. Referring to the likelihood table, the soft-decision decoding module 13 can determine likelihood.

Furthermore, the soft-decision decoding module 13 plays a role in correcting data whose level of certainty (likelihood) has been determined to be low to complement the hard-decision decoding module 11.

When 4-level data is read, the potential of the word line is changed from VA to VB and to VD in that order, thereby reading lower-page data Lower and upper-page data Upper. Since 4-level data is read by reading the lower-page data and upper-page data, the relationship between data Upper (pre1) and upper-page data Upper is as shown in FIG. 5.

When a data error has occurred (e.g., when data “00” has been read erroneously as data “10” whose threshold value distribution is adjacent to that of data “00”), the hard-decision decoding module 11 subjects the read 4-level data to error detection and error correction on the basis of redundant data.

However, when 4-level data is read simply as bit data, it is determined only whether the validity of the threshold value distribution is precisely “0” or “1” and the correcting capability is determined precisely only by the amount of redundant data added to the information bit. As memory cells have been miniaturized further and n in n-level data stored on one memory cell has been made larger, the rate of occurrence of write errors increases. Therefore, it might be difficult to cope with errors only with the hard-decision decoding module 11 using redundant data.

Therefore, in the first embodiment, when there is a high probability that the hard-decision decoding module 11 will fail error correction, likelihood representing the certainty of multibit data is produced. Using the likelihood, the soft-decision decoding module 13 makes error corrections, which enables error corrections to be made without increasing the number of bits in the redundant data.

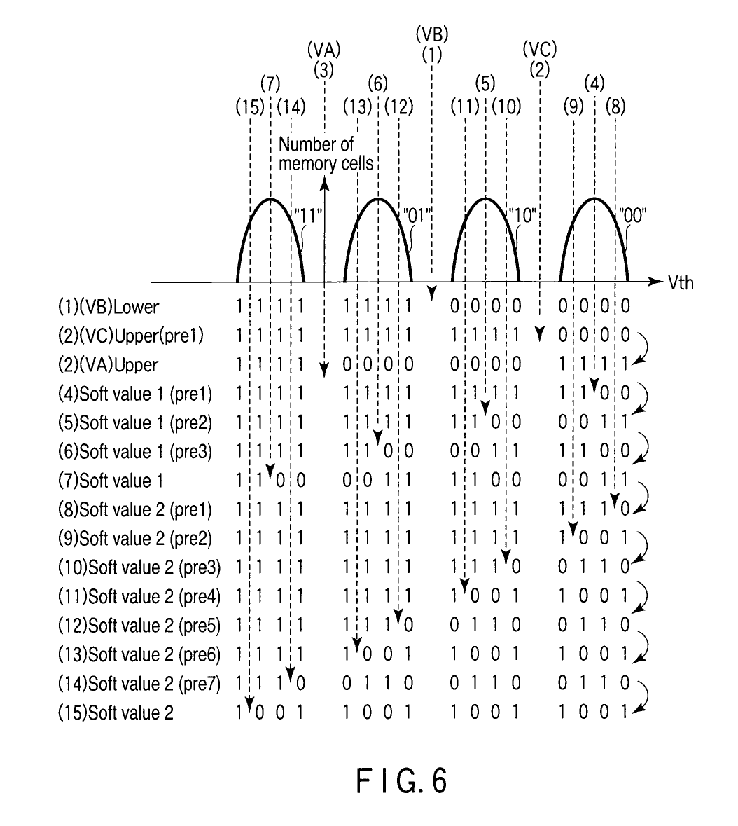

Soft-value data is created by generating a plurality of soft-value read voltages (4) to (15) whose magnitudes are between the upper limit and lower limit of each of the threshold value distributions of data “11,” “01,” “10,” and “00” as shown in, for example, FIG. 6 and reading data. From the soft-value data, it can be determined not only which one of 4-level data items (“11,” “01,” “10,” “00”) a memory cell to be read from holds but also whether the memory cell has a threshold voltage near the center (peak) of one threshold value distribution or whether the memory cell has a threshold voltage near the upper limit or lower limit of the threshold value distribution.

When the threshold voltage is near the upper limit or lower limit of the threshold value distribution, the probability that a data error has occurred is higher than when the threshold voltage is near the center of the threshold value distribution. In other words, the former has a lower level of certainty (or likelihood) of multibit data than the latter. The soft-decision decoding module 13 corrects 4-level data in a memory cell from which soft-value data whose level of certainty (likelihood) has been determined to be lower has been obtained and performs syndrome calculations after the correction repeatedly until all of the syndromes have become “0.”

In FIG. 6, each of soft-value read voltages (4) to (7) is a voltage near the midpoint (or midway between the upper limit and lower limit) of the threshold value distribution of each of data “11,” “01,” “10,” “00,” respectively. The remaining soft-value read voltages (8) to (15), together with soft-value read voltages (4) to (7), are set so as to divide each threshold value distribution at almost regular intervals. That is,

(i) soft-value read voltages (4), (8), (9) are set so as to divide the threshold value distribution of data “00” at almost regular intervals

(ii) soft-value read voltages (5), (10), (11) are set so as to divide the threshold value distribution of data “10” at almost regular intervals

(iii) soft-value read voltages (6), (12), (13) are set so as to divide the threshold value distribution of data “01” at almost regular intervals

(iv) soft-value read voltages (7), (14), (15) are set so as to divide the threshold value distribution of data “11” at almost regular intervals

This is an example when the threshold value distributions are almost Gaussian distributions. The threshold value distributions are not limited to this example. Each threshold value distribution may be divided at slightly nonuniform intervals, depending on the shape of the distribution. The number of divisions in each threshold value distribution, that is, the number of soft-value read voltages included in each threshold value distribution, is not restricted to 3 and may be 4 or more.

Next, the procedure for creating soft-value data will be explained with reference to FIG. 6. The word line voltage is set to (1) multibit data read voltage VB, (2) multibit data read voltage VC, (3) multibit data read voltage VA in that order, thereby reading lower-page data Lower, preliminary upper-page data Upper (pre1), upper-page data Upper.

A matrix of “1s” and “0s” shown in the lower half of FIG. 6 lists the magnitude of the threshold voltage of the memory cell, obtained page data, and soft values (soft value 1 (prei), soft value 2 (prei), soft value 1, soft value 2) when the word line voltage is changed from (1) to (2), and to . . . , (15).

Next, the word line voltage is set to soft-value read voltages (4) to (7) near the midpoint between the upper limit and lower limit of each threshold value distribution in that order (that is, lowering the voltage stepwise). First, soft-value data soft value 1 (pre1) read when soft-value read voltage (4) has been set is read as data “0” from only a memory cell which has a higher threshold voltage than the right half of the threshold value distribution of data “00,” and otherwise as data “1.” The read soft value 1 (pre1) is held in a temporary data cache (TDC), passes through a primary data cache (PDC), and is held in a data cache (DDC) in the data input/output buffer 24.

Next, the soft-value read voltage (5) is set to read soft-value data soft value 1 (pre2). The soft value 1 (pre2) is read as data “0” from only a memory cell which has a higher threshold voltage than the right half of the threshold value distribution of data “10,” and otherwise as data “1” and is stored in TDC. Here, when soft value 1 (pre1) is held in DDC, if soft value 1 (pre1) held in DDC is “0,” the data held in TDC is inverted forcedly to “1” (see arrows in FIG. 6). That is, when the soft-value read voltage is lowered stepwise, if neither a first soft-value read voltage nor a second soft-value read voltage one step lower than the first soft-value read voltage causes the memory cell to conduct, the data obtained with the second soft-value read voltage is inverted and the inverted data is used as a soft value.

Similarly, soft-value read voltages (6) and (7) are applied as word line voltages. If the preceding soft value 1 (prei) is “0,” the data is inverted. Data created by soft-value read voltage (7) is soft value 1. Soft value 1, together with soft value 2, is used to do likelihood calculations at a likelihood computing circuit 102.

Then, the word line voltage is set to soft-value read voltages (8) to (15) in that order (that is, the word line voltage is lowered stepwise). Soft-value read voltages (8) to (15) are the same as soft-value read voltages (4) to (7) in that the data is inverted when the preceding soft value held in DDC is “0.” Soft value 2 generated by applying soft-value read voltage (15) as a word line voltage is used together with soft value 1 at the soft-decision decoding module 13 to do likelihood calculations.

The soft-decision decoding module 13 makes corrections by trial and error repeatedly on the basis of the calculated likelihood. When soft-decision decoding module 13 does not complete the correction even if it has repeated the correction a specific number of times, it determines that the correction has failed and discards the calculated likelihood. Then, the soft-decision decoding module 13 makes the number of soft-value read voltages larger than 12, soft-value read voltages (4) to (15), (e.g., 16), obtains new soft values, and calculates likelihood. This makes it possible to determine the certainty (likelihood) of multibit data more accurately and increase the probability that an error will be corrected. It is preferable to increase the number of soft-value read voltages stepwise from the viewpoint of keeping the data reading speed of a nonvolatile semiconductor device, while eliminating errors.

As described above, with the first embodiment, the hard-decision decoding module 11 and soft-decision decoding module 13 are provided. When the hard-decision decoding module 11 has been started and more than a specific number of parity errors have not been detected, the output selection module 15 selects the decoding result of the hard-decision decoding module 11. When more than a specific number of parity errors have been detected, the soft-decision decoding module 13 is started and the output selection module 15 selects the decoding result of the soft-decision decoding module 13, which enables the reliability of data read from a NAND flash memory or the like to be improved and the overall processing time to be shortened.

### Second Embodiment

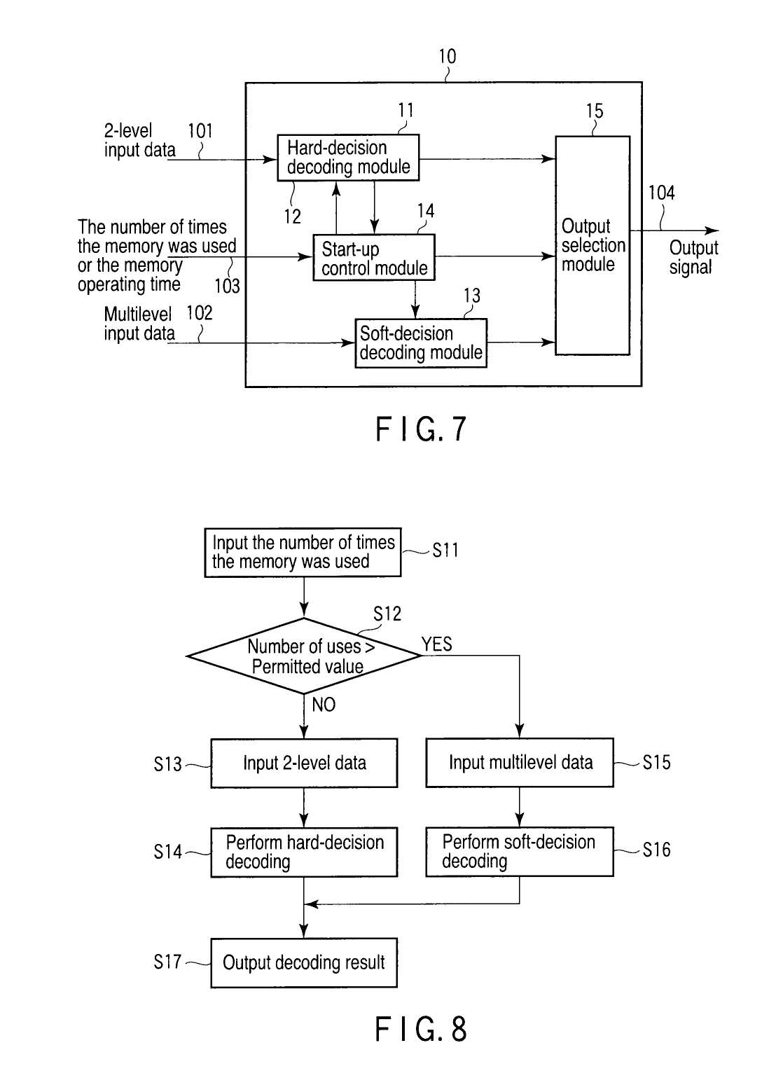

FIG. 7 is a block diagram schematically showing an error correction decoding apparatus according to a second embodiment. In FIG. 7, the same parts as those of FIG. 1 are indicated by the same reference numerals and a detailed explanation of them will be omitted.

The basic configuration of the second embodiment is the same as that of the first embodiment. The second embodiment differs from the first embodiment in that a signal representing the number of times the memory was used or the memory operating time is used as a start-up signal 103 and that a start-up control module 14 selectively starts the hard-decision decoding module 11 or soft-decision decoding module 13. That is, on the basis of the start-up signal 103, the start-up control module 14 starts only either the hard-decision decoding module 11 or soft-decision decoding module 13.

In the apparatus, the NAND flash memory 20 supplies a signal 103 representing the number of times the memory was used or the memory operating time and inputs the signal to the start-up control module 14 (step S11). As for the number of times the memory was used, the NAND flash memory 20 memorizes the number of times the memory cell was read/written and outputs the number as a start-up signal 103. As for the memory operating time, the NAND flash memory 20 is caused to have the function of recognizing the manufacturing time (or starting time of use) of a memory cell and the current time and outputs the time elapsed between the manufacturing time and the current time as a start-up signal 103.

Next, the start-up control module 14 determines whether the number of times the memory was used or the memory operating time has exceeded a specific value (permitted value) (step S12). If the number of times the memory was used or the memory operating time has not exceeded the permitted value, the start-up control module 14 inputs 2-level input data 101 (step S13) and starts the hard-decision decoding module 11 (step S14). If the number of times the memory was used or the memory operating time has exceeded the specific value, the start-up control module 14 inputs multilevel input data 102 (step S15) and starts the soft-decision decoding module 13 (step S16).

Then, if the number of times the memory was used or the memory operating time has not exceeded the permitted value, the output selection module 15 selects the hard-decision decoding result and outputs the selected signal. If the number of times the memory was used or the memory operating time has exceeded the permitted value, the output selection module 15 selects the soft-decision decoding result and outputs the selected signal.

The flash memory deteriorates with age according to the number of uses or operating time and the probability that hard-decision decoding will lack the error correction capability might become higher. In such a case, it is preferable to start only the soft-decision decoding module 13 from the beginning without starting the unnecessary hard-decision decoding module 11.

As described above, with the second embodiment, a combination of hard-decision decoding and soft-decision decoding not only improves the reliability of data read from a NAND flash memory or the like but also enables the activation and execution of hard-decision decoding to be omitted when there is a high probability that hard-decision decoding will lack the error correction capability. Consequently, the second embodiment produces the effects of reducing the overall power consumption, shortening the operating time, and increasing the error correction capability.

### Third Embodiment

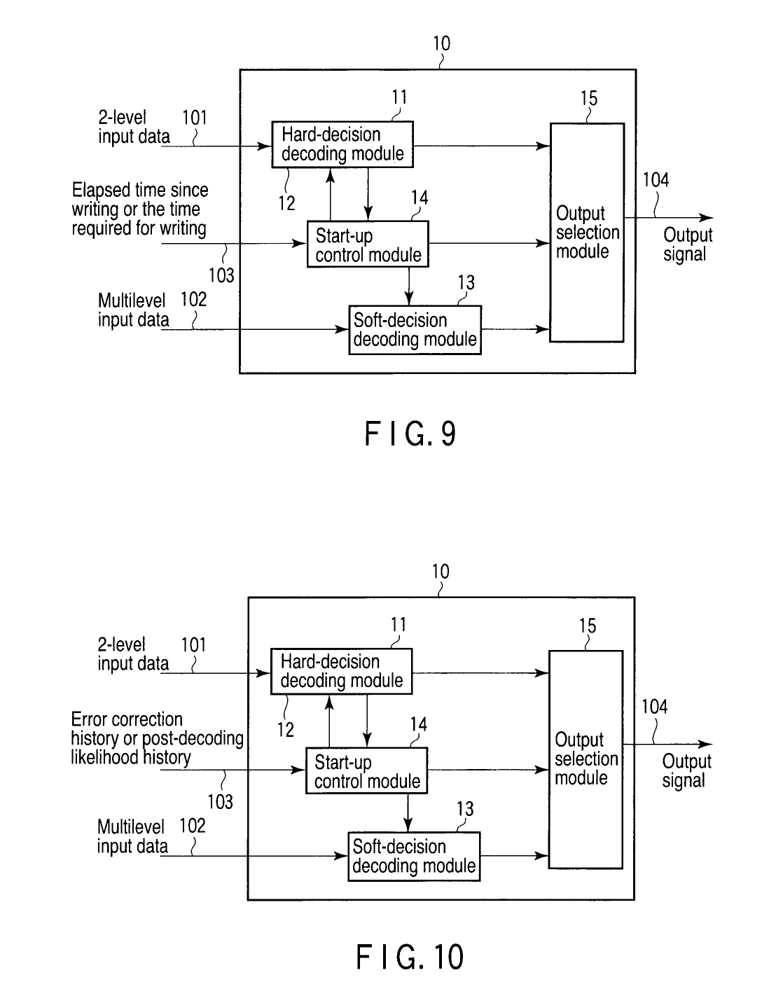

FIG. 9 is a block diagram schematically showing an error correction decoding apparatus according to a third embodiment. In FIG. 9, the same parts as those of FIG. 7 are indicated by the same reference numerals and a detailed explanation of them will be omitted.

The third embodiment differs from the second embodiment in that a signal representing the elapsed time since the memory write time or the time required for writing is used as a start-up signal and that the start-up control module 14 selectively starts the hard-decision decoding module 11 or soft-decision decoding module 13.

In the apparatus, the NAND flash memory 20 supplies a signal 103 representing the elapsed time since the memory write time or the time required for writing and inputs the signal 103 to the start-up control module 14. As for the elapsed time, the NAND flash memory 20 is caused to have the function of recognizing the time when a memory cell was written into and the current time, memorizes the elapsed time between the write time and the current time, and outputs the elapsed time as a start-up signal 103. As for the time required for writing, the NAND flash memory 20 memorizes a rewrite history in writing data into a memory cell and outputs the time required for writing as a start-up signal 103.

If the elapsed time or the time required has not exceeded a specific value, the start-up control module 14 starts the hard-decision decoding module 11 and the output selection module 15 selects the hard-decision decoding result. If the elapsed time or the time required has exceeded the specific value, the start-up control module 14 starts the soft-decision decoding module 13 and the output selection module 15 selects the soft-decision decoding result.

As described above, when the elapsed time since the writing of a memory cell or the time required for writing has exceeded a predetermined time, hard-decision decoding is skipped and only soft-decision decoding is performed, which enables the activation and execution of hard-decision decoding to be omitted when there is a high probability that hard-decision decoding will lack the error correction capability. Accordingly, the third embodiment produces the same effect as that of the second embodiment.

### Fourth Embodiment

FIG. 10 is a block diagram schematically showing an error correction decoding apparatus according to a fourth embodiment. In FIG. 10, the same parts as those of FIG. 7 are indicated by the same reference numerals and a detailed explanation of them will be omitted.

The fourth embodiment differs from the second embodiment in that a signal representing the number of memory error bits history or post-decoding likelihood history is used as a start-up signal and that the start-up control module 14 selectively starts the hard-decision decoding module 11 or soft-decision decoding module 13.

In the apparatus, the NAND flash memory 20 supplies a signal 103 representing the number of memory error bits history or post-decoding likelihood history and inputs the signal 103 to the start-up control module 14. As for the number of memory error bits history, the NAND flash memory 20 memorizes a history of past decoding processes and the number of corrected bits and outputs the number as a start-up signal 103. As for post-decoding likelihood history, the NAND flash memory 20 memorizes a history of past decoding processes and the likelihood of decoding bits and outputs the likelihood as a start-up signal 103.

If the number of error bits history or post-decoding likelihood history has not exceeded a specific value, the start-up control module 14 starts the hard-decision decoding module 11 and the output selection module 15 selects the hard-decision decoding result. If the number of error bits history or post-decoding likelihood history has exceeded the specific value, the start-up control module 14 starts the soft-decision decoding module 13 and the output selection module 15 selects the soft-decision decoding result.

As described above, when the number of memory error bits history is larger than a predetermined value or the post-decoding likelihood history is smaller than the permitted value, hard-decision decoding is skipped and only soft-decision decoding is performed, which enables the activation and execution of hard-decision decoding to be omitted when there is a high probability that hard-decision decoding will lack the error correction capability. Accordingly, the third embodiment produces the same effect as that of the second embodiment.

(Modification)

The present invention is not limited to the above embodiments. While in the embodiments, 4-level data has been used as multibit data, the invention is not limited to this. It goes without saying that the invention may be applied to N-level data (N being an integer not less than 1), such as 8-level data or 16-level data.

Errors in multi-page data constituting multibit data may be detected and corrected independently or cooperatively on the basis of redundant data added to each data item. In the latter case, as many storage elements (shift registers) as correspond to the number of page data items are provided in a data input/output buffer. After multi-page data is stored in the storage elements, the data can be read.

While in the embodiments, an error in the data read from the NAND flash memory has been corrected, the method can, of course, be applied to other memories. Furthermore, the method can be applied to the error correction of communication data in addition to data read from the memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions

What is claimed is:

1. An error correction decoding apparatus comprising:
a hard-decision decoding module which performs hard-decision decoding using a signal with 2 levels per bit as input data and runs a parity check on the input data;
a soft-decision decoding module which performs soft-decision decoding using a signal with the number of multiple levels per bit larger than 2 as input data;
a start-up control module which controls the start-up of the hard-decision decoding module and the start-up of the soft-decision decoding module; and
an output selection module to which the output signal of the hard-decision decoding module and the output signal of the soft-decision decoding module are input and which selects one of the output signals and outputs the selected one,
wherein the start-up control module causes the output selection module to select the decoding result of the hard-decision decoding module when more than a specific number of parity errors have not been detected as a result of the start-up of the hard-decision decoding module, and causes the soft-decision decoding module to start and the output selection module to select the decoding result of the soft-decision decoding module when more than a specific number of parity errors have been detected as a result of the start-up of the hard-decision decoding module.

2. The error correction decoding apparatus according to claim 1, wherein the hard-decision decoding module includes a parity check module which detects a data error by using redundant data for the input data.

3. The error correction decoding apparatus according to claim 2, wherein the start-up control module accumulates the number of parity errors in a plurality of data items and compares the number with a permitted value to determine whether more than a specific number of parity errors have been detected.

4. The error correction decoding apparatus according to claim 1, wherein the input data to the hard-decision decoding module and the input data to the soft-decision decoding module are output from the NAND flash memory, and
the NAND flash memory includes a memory cell array which has memory cells storing data arranged in a matrix, a word line control circuit for controlling a word line voltage, and a bit line control circuit for controlling bit lines voltage.

5. The error correction decoding apparatus according to claim 4, wherein the word line control circuit applies a voltage for writing and reading 2-level data as a word line voltage to a word line and further applies a plurality of voltages (soft-value read voltages) whose magnitudes are between the upper limit and lower limit of a threshold value distribution of stored data in the memory cell as word line voltages to a word line to create soft-value data.

6. An error correction decoding apparatus comprising:
a hard-decision decoding module which performs hard-decision decoding using a signal with 2 levels per bit, which is a value read from a semiconductor memory, as input data;
a soft-decision decoding module which performs soft-decision decoding using a signal with the number of multiple levels per bit larger than 2, which is a value read from the semiconductor memory, as input data;
a start-up control module to which a start-up signal obtained by digitizing information on the semiconductor memory is input and which controls the start-up of the hard-decision decoding module and the start-up of the soft-decision decoding module; and
an output selection module to which the output of the hard-decision decoding module and the output of the soft-decision decoding module are input and which selects one of the outputs and outputs the selected one,
wherein the start-up control module causes the hard-decision decoding module to start and the output selection module to select the output signal of the hard-decision decoding module when the start-up signal is within a predetermined permitted value, and causes the soft-decision decoding module to start and the output selection module to select the output signal of the soft-decision decoding module when the start-up signal is outside the permitted value.

7. The error correction decoding apparatus according to claim 6, wherein the semiconductor memory is a NAND flash memory.

8. The error correction decoding apparatus according to claim 6, wherein the start-up signal input to the start-up control module is a signal representing the number of times the semiconductor memory was used, and
the start-up control module starts the soft-decision decoding module without starting the hard-decision decoding module and causes the output selection module to select the decoding result of the soft-decision decoding module when the number of times the memory was used is larger than the permitted value.

9. The error correction decoding apparatus according to claim 6, wherein the start-up signal input to the start-up control module is a signal representing the operating time of the semiconductor memory, and
the start-up control module starts the soft-decision decoding module without starting the hard-decision decoding module and causes the output selection module to select the decoding result of the soft-decision decoding module when the operating time of the memory is longer than the permitted value.

10. The error correction decoding apparatus according to claim 6, wherein the start-up signal input to the start-up control module is a signal representing an elapsed time since the writing time of the semiconductor memory, and
the start-up control module starts the soft-decision decoding module without starting the hard-decision decoding module and causes the output selection module to select the decoding result of the soft-decision decoding module when the elapsed time is longer than the permitted value.

11. The error correction decoding apparatus according to claim 6, wherein the start-up signal input to the start-up control module is a signal representing the time required for the writing of the semiconductor memory, and
the start-up control module starts the soft-decision decoding module without starting the hard-decision decoding module and causes the output selection module to select the decoding result of the soft-decision decoding module when the time required for the writing is longer than the permitted value.

12. The error correction decoding apparatus according to claim 6, wherein the start-up signal input to the start-up control module is a signal representing the number of error bits history in the semiconductor memory, and
the start-up control module starts the soft-decision decoding module without starting the hard-decision decoding module and causes the output selection module to select the decoding result of the soft-decision decoding module when the number of error bits history is larger than the permitted value.

13. The error correction decoding apparatus according to claim 6, wherein the start-up signal input to the start-up control module is a signal representing post-decoding likelihood history of the semiconductor memory, and
the start-up control module starts the soft-decision decoding module without starting the hard-decision decoding module and causes the output selection module to select the decoding result of the soft-decision decoding module when the post-decoding likelihood history is lower than the permitted value.

14. An error correction decoding method comprising:
inputting a signal with 2 levels per bit as first input data;
performing hard-decision decoding on the first input data and running a parity check;
determining whether the number of parity errors detected by the parity check is within a permitted value;
selecting the hard-decision decoding result and outputting the selected result when it has been determined that the number of parity errors is within the permitted value; and
inputting a signal with the number of multiple levels per bit larger than 2 as second input data, performing soft-decision decoding on the second input data, selecting the soft-decision decoding result, and outputting the selected result, when it has been determined that the number of parity errors has exceeded the permitted value.

15. The error correction decoding method according to claim 14, wherein the performing soft-decision decoding includes starting soft-decision decoding before the hard-decision decoding is completed.

16. The error correction decoding method according to claim 14, wherein the determining whether the number of parity errors detected by the parity check is within a permitted value includes running a parity check using redundant data included in the first input data, accumulating the number of parity errors in a plurality of data items, and comparing the number with a permitted value.

17. The error correction decoding method according to claim 14, wherein the first input data and the second input data are output data of the NAND flash memory.
